(19) United States
(12) Patent Application Publication
(10) Pub. No.: US 2001/0038552 A1
(43) Pub. Date: Nov. 8, 2001

(54) Semiconductor memory with switches for reducing leakage current

(75) Inventor: Kazunari Ishimaru, Kanagawa-ken (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: KABUSHIKI KAISHA TOSHIBA, Kawasaki-shi (JP)

(21) Appl. No.: 09/814,724

(22) Filed: Mar. 23, 2001

(30) Foreign Application Priority Data
Mar. 24, 2000 (JP) P2000-85058
Mar. 15, 2001 (JP) P2001-74700

(51) Int. Cl. G11C 11/34; G11C 7/00

(52) U.S. Cl. 365/181; 365/182; 365/190

(57) ABSTRACT

A semiconductor memory with static memory cells has an n-well in which pMOS transistors are formed and a p-well in which nMOS transistors are formed. The n- and p-wells are divided into blocks each containing a given number of memory cells. The n- and p-wells in each block receive voltages that vary depending on whether or not the memory cells are selected. If the memory cells are selected to operate, the threshold voltage of each transistor in the memory cells is decreased to increase current to be taken out of the memory cells. If the memory cells are not selected, the threshold voltage is increased to reduce leakage current of the memory cells. This arrangement suppresses standby current and improves the operation speed of the memory cells.

### CROSS REFERENCE TO RELATED APPLICATIONS

This application claims benefit of priority under 35 USC 119 based on Japanese Patent Application P2000-085058 filed Mar. 24, 2000 and Japanese Patent Application P2001-074700 filed Mar. 15, 2001 the entire contents of which are incorporated by reference herein.

### BACKGROUND OF THE INVENTION

1. Field of the Invention

The present invention relates to semiconductor devices with static memory cells, and particularly, to memory cells of semiconductor memories such as SRAMs.

2. Description of the Related Art

Higher integration of semiconductor elements is accelerating the development of smaller MOS transistors, and the smaller MOS transistors are promoting smaller memory cells. In the course of making smaller MOS transistors, the performance of the MOS transistors has been improved. However, the small MOS transistors or fine memory cells involve narrow channels to reduce current of each memory cell. A reduction in the memory cell current is not preferable because it leads to degradation in operation speed. To improve the operation speed of a memory cell, current of the memory cell should be increased.

The memory cell current is increasable by widening the channel width of a transistor in each memory cell or by decreasing the threshold voltage of the transistor. Widening the channel width of a transistor has a problem of increasing the size of a memory cell.

Decreasing the threshold voltage may increase the memory cell current without widening the channel width. This technique, however, has a problem of increasing standby current, i.e., leakage current. The leakage current consumes unignorable power in a large-capacity semiconductor memory employing fine memory cells, and therefore, is disadvantageous when the memory is applied to a portable device driven by battery, for example. There is a need of providing large-capacity, low-leakage-current, high-speed SRAMs.

### SUMMARY OF THE INVENTION

The present invention is to provide a large-capacity, high-speed semiconductor memory capable of securing a required memory cell current at a low source voltage and suppressing standby current.

According to the present invention, there is provided a semiconductor memory with static memory cells, comprising a first-conductivity-type well contained in the memory cells, configured to include second-conductivity-type transistors, a second-conductivity-type well contained in the memory cell, configured to include first-conductivity-type transistors, a first power source line configured to supply a first voltage, a second power source line configured to supply a second voltage, a third power source line configured to supply a third voltage; and first switch coupled to the first and second power source lines, configured to provide the first-conductivity-type well with one of the first and second voltages in response to a switching signal.

According to another aspect of the present invention, there is provided a semiconductor memory with static memory cells, comprising a first-conductivity-type well contained in each of the memory cells and including second-conductivity-type transistors, a second-conductivity-type well contained in the memory cell and including first-conductivity-type transistors, a first power source line coupled to the first-conductivity-type well, configured to supply one of first and second voltages, a second power source line configured to supply a third voltage, and switching means coupled to the first power source line, configured to provide the first power source line with one of the first and second voltages in response to a switching signal.

The term “first” and “second” conductivity types are opposite to each other. If the first conductivity type is “n,” the second conductivity type is “p.” If the first conductivity type is “p,” the second conductivity type is “n.” The term MIS (metal insulator semiconductor) includes MOS (metal oxide semiconductor).

### BRIEF DESCRIPTION OF THE DRAWINGS

The objects, features, and advantages of the present invention will become more apparent from the following description of the embodiments taken in conjunction with the accompanying drawings, in which:

FIG. 1 is a block diagram showing memory cell blocks of an SRAM according to an embodiment of the present invention;

FIG. 2 is a circuit diagram showing an example of a memory cell in one of the memory cell blocks of FIG. 1;

FIG. 3 is a circuit diagram showing examples of switches provided for each memory cell block of FIG. 1;

FIG. 4 is a circuit diagram showing examples of other switches applicable to the memory cell block of FIG. 1;

FIG. 5 is a timing chart showing the operation of the switches of FIG. 3; and

FIG. 6 is a layout model showing the memory cell blocks of FIG. 1.

### DESCRIPTION OF THE PREFERRED EMBODIMENTS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

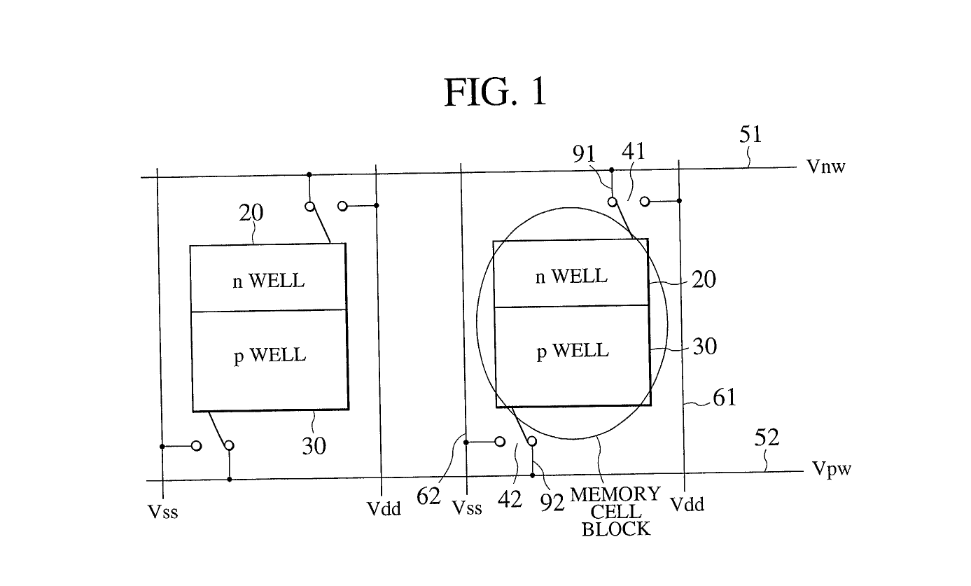

FIG. 1 is a block diagram showing memory cell blocks of an SRAM according to an embodiment of the present invention. Generally, SRAMs employ perfect CMOS memory cells. Accordingly, each memory cell block of the SRAM of FIG. 1 has an n-type well (hereinafter referred to as n-well) 20 to form pMOS transistors, and a p-type well (hereinafter referred to as p-well) 30 to form nMOS transistors. Pairs of n-well 20 and p-well 30 are divided by the memory cell blocks. Each memory cell block has a switch 41 for connecting the n-well 20 to one of a power source line 51 to apply voltage Vnw and a power source line 61 to apply voltage Vdd, and a switch 42 for connecting the p-well 30 to one of a power source line 52 to apply voltage Vpw and a power source line 62 of voltage Vss. These voltages have relationships of Vnw>Vdd, and Vss>Vpw.

In an SRAM employing perfect CMOS memory cells, n- and p-wells extend like stripes in parallel with each other, and the p-well is fixed at a ground voltage Vss and the n-well at a power source voltage. Instead, the present invention divides p- and n-wells of an SRAM into groups each containing a given number of memory cells. The embodiment of FIG. 1 divides p- and n-wells along word lines into memory cell blocks each containing, for example, 32 or 64 memory cells.

Each divided well is connected to a voltage through one of the switches 41 and 42. For example, the p-well 30 is connected to Vpw of, for example, −1 V that is lower than the ground voltage Vss through the switch 42, and the n-well is connected to Vnw of, for example, +1 V that is higher than the power source voltage Vdd through the switch 41. These voltages are generated by a peripheral circuit and is supplied through the power source lines 51, 52, 61, and 62.

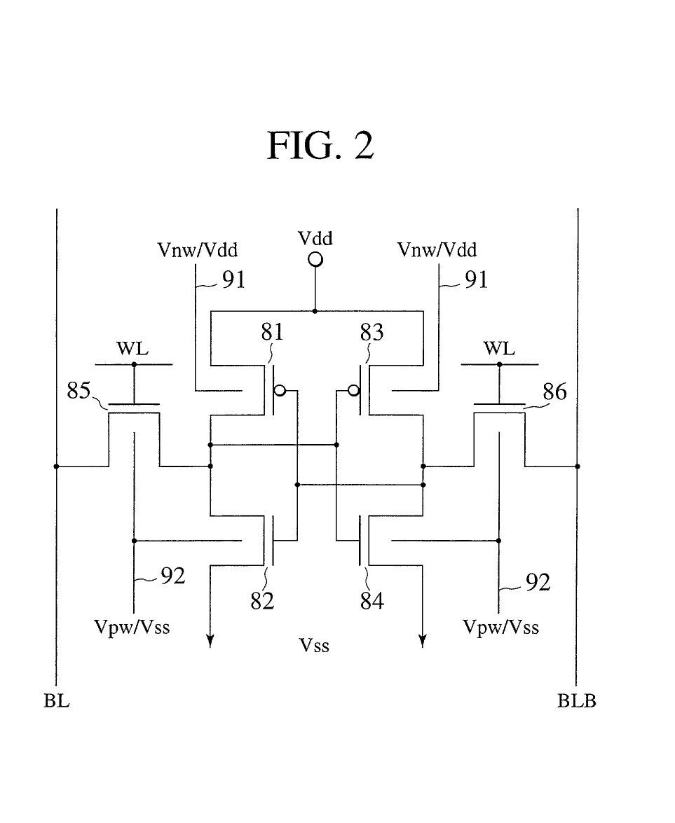

FIG. 2 is a circuit diagram showing a memory cell in one of the memory cell blocks of FIG. 1. The memory cell has an inverter comprising a pMOS transistor 81 and an nMOS transistor 82, and an inverter comprising a pMOS transistor 83 and an nMOS transistor 84. These inverters are oppositely connected in parallel with each other to form a memory part. To access the memory part, the memory cell has nMOS transistors 85 and 86 serving as switches connected to a word line WL.

Generally, a p-well for nMOS transistors is grounded, and an n-well for pMOS transistors is connected to a power source. According to this embodiment according to the present invention, a line 91 applies Vnw or Vdd to an n-well, and a line 92 applies Vpw or Vss to a p-well.

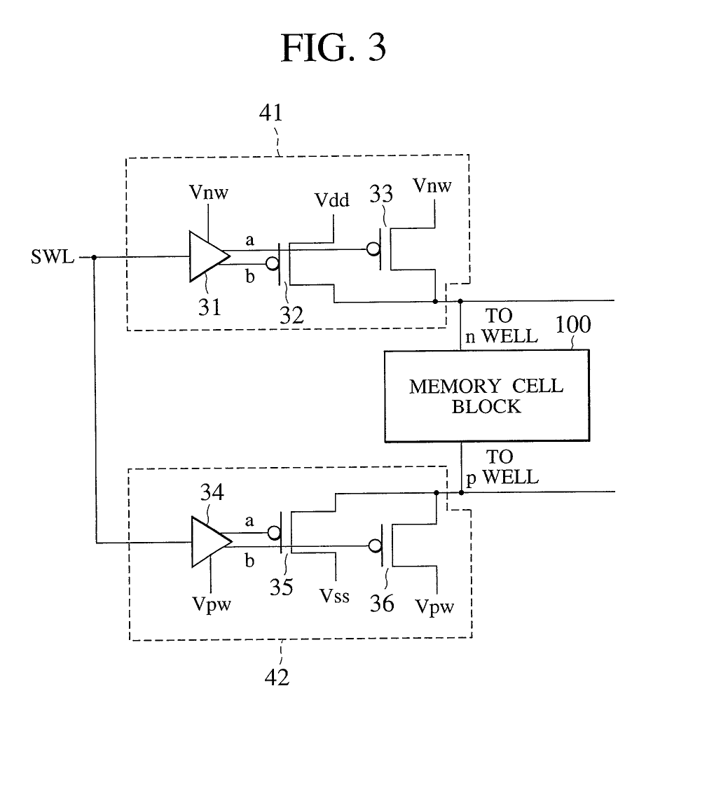

FIG. 3 is a circuit diagram showing the details of the switches 41 and 42 of FIG. 1. The switch 41 includes a level shifter 31, a pMOS transistor 32, and a pMOS transistor 33. The switch 42 includes a level shifter 34, an nMOS transistor 35, and an nMOS transistor 36.

The level shifter 31 inputs Vnw, and the level shifter 34 inputs Vpw. The level shifters 31 and 34 are connected to a section word line SWL. The pMOS transistors 32 and 33 are connected to the line 91 shown in FIG. 1 that is connected to the n-well of the memory cell block 100. The nMOS transistors 35 and 36 are connected to the line 92 shown in FIG. 1 that is connected to the p-well of the memory cell block 100.

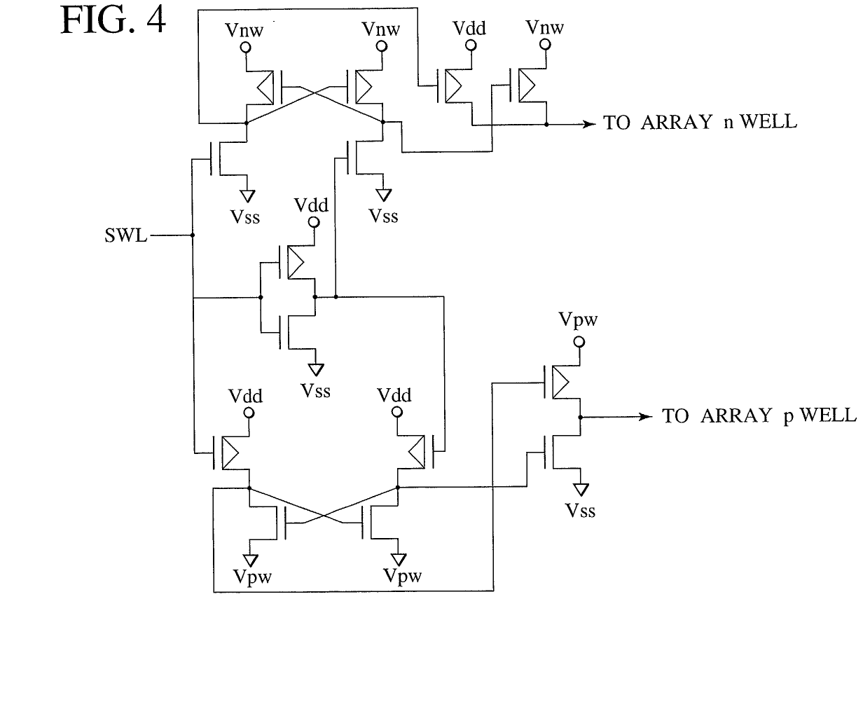

FIG. 4 is a circuit diagram showing other switches replaceable with the switches 41 and 42. The switches of FIG. 4 switch voltages supplied to wells in response to a signal SWL. These switches include a combination of nMOS and pMOS transistor pairs. This arrangement is advantageous in that the switches are formed only by changing connection wiring in a cell layout since each memory cell itself has nMOS and pMOS transistor pairs. MOSFETs in memory cells can be used for the switches since these switches need no large size of transistors. Generally, a memory cell array involves iterated patterns. However, there may be problems of irregular dimensions since the edge of the array involves irregularities. To prevent such irregularities, there is a technique of optically correcting patterns and a technique of placing dummy patterns. Between the two techniques, often taken is the dummy pattern technique. The dummy patterns produce a dead area. The embodiment of FIG. 4 uses the dummy patterns, i.e., dummy cells to form the switches, thereby eliminating the dead area.

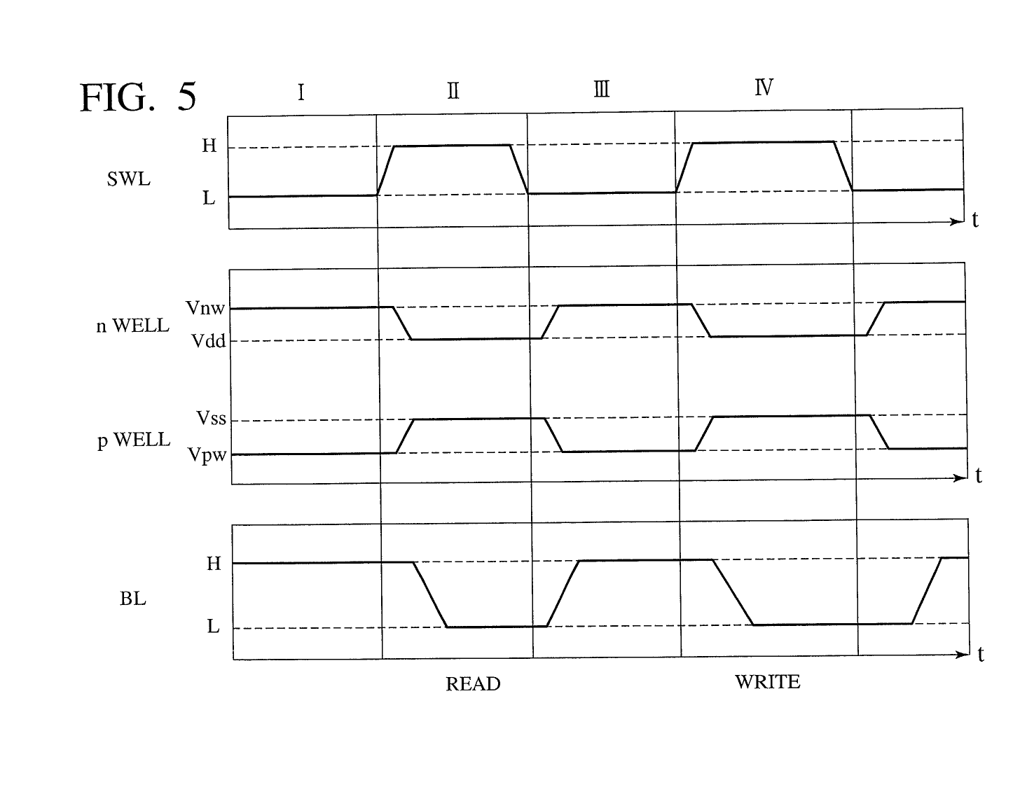

FIG. 5 is a timing chart showing the operation of the switches of FIG. 3. In FIG. 5, an abscissa represents time. Shown in FIG. 5 are the signal SWL, voltages supplied to the n- and p-wells in response to the signal SWL, and read and write timing on a bit line BL. This timing chart shows “0” read operations and “0” write operations During standby periods I and III of FIG. 5, the memory cell block 100 is not selected and the section word line SWL is at low level. As a result, an output “a” of the level shifter 31 shown in FIG. 3 is low, and an output “b” of the level shifter 31 shown in FIG. 3 is high. Accordingly, the pMOS transistor 32 is OFF, and the pMOS transistor 33 is ON to apply Vnw to the n-well of the memory cell block 100.

During selecting periods II and IV of FIG. 5, the section word line SWL is at high level. As a result, the output “a” of the level shifter 31 shown in FIG. 3 is high, and the output “b” thereof is low. Accordingly, the pMOS transistor 33 is OFF and the pMOS transistor 32 is ON to apply Vdd to the n-well of the memory cell block 100. If this selected period is for a read operation, a word line is high to read “0.” At this time, the voltage of the bit line BL drops. If this selected period is for a write operation, the word line is high to write “0.”

On the other hand, during the standby periods I and III of FIG. 5, an output “a” of the level shifter 34 is low, and an output “b” thereof is high. Accordingly, the nMOS transistor 35 is OFF, and the nMOS transistor 36 is ON to apply Vpw to the p-well of the memory cell block 100.

During the selected period II and IV of FIG. 5, the section word line SWL is at high level. As a result, the output “a” of the level shifter 34 is high, and the output “b” thereof is low. Accordingly, the nMOS transistor 36 is OFF and the nMOS transistor 35 is ON to apply Vss to the p-well of the memory cell block 100.

The threshold voltage Vth of each transistor in each memory cell block increases as the voltage of the p-well decreases, or as the voltage of the n-well increases. In the p-well, there is the following relationship:

Vth∝(Vg−Vw) (Vth being proportional to (Vg−Vw)) (1)

where Vg is a gate voltage of an nMOS transistor in the p-well, and Vw is a voltage applied to the p-well. In the n-well, there is the following relationship:

Vth∝(Vg+Vw) (Vth being proportional to (Vg+Vw)) (2)

where Vg is a gate voltage of a pMOS transistor in the n-well, and Vw is a voltage applied to the n-well.

During the standby period, applying Vpw, which is lower than Vss, as Vw to the p-well increases the threshold voltage Vth due to the relationship (1), to reduce leakage current from each memory cell. During the selecting period of the memory cell block 100, applying Vss as Vw to the p-well decreases the threshold voltage Vth, to increase current to be taken out of each memory cell.

Similarly, during the standby period, applying Vnw, which is higher than Vdd, as Vw to the n-well increases the threshold voltage Vth due to the relationship (2), to reduce leakage current from each memory cell. During the selecting period of the memory cell block 100, applying Vdd as Vw to the n-well decreases the threshold voltage Vth, to increase current to be taken out of each memory cell. This results in improving the read operation speed on the SRAM.

This embodiment according to the present invention carries out the switching of the voltage Vw applied to a given well according to the voltage of the section word line SWL When the memory cell block 100 is selected, the section word line SWL is high to change the switches 42 and 41 to apply Vss to the p-well and Vdd to the n-well, thereby decreasing the threshold voltage Vth. When the memory cell block 100 is not selected during a standby period, the switches 42 and 41 are changed to apply Vpw to the p-well and Vnw to the n-well, thereby increasing the threshold voltage.

Generally, a large-capacity, low-power-consumption SRAM has a threshold voltage in the range of 0.6 to 0.8 V for memory cell MOSFET. To operate such an SRAM at a speed of, for example, 50 ns, it needs a voltage of 1.8 V or higher. To operate the SRAM at 1.5 V or lower, the threshold voltage must be decreased. This, however, increases leakage current. If the threshold voltage is decreased by about, for example, 0.2 V, the leakage current is increased prohibitively.

To avoid this problem, this embodiment according to the present invention applies, during a standby period, substrate potentials (Vpw, Vnw) to wells, to increase the threshold voltage and reduce leakage current. During a selecting period, i.e., an operation period, this embodiment according to the present invention releases the substrate potentials from the wells, to decrease the threshold voltage and increase current of each memory cell. As a result, SRAM of this embodiment according to the present invention is capable of operating at high speed even at a source voltage of lower than 1.5 V, for example, 1 V.

The present invention releases the substrate biases (Vpw, Vnw) during a read operation, to decrease the threshold voltage and increase driving power, thereby realizing a high-speed operation.

Generally, the resistance of a well is in the range of several hundred to kilo-ohm, and together with junction capacitance, increases an RC delay. The present invention divides wells into sections or blocks, to reduce the RC delay.

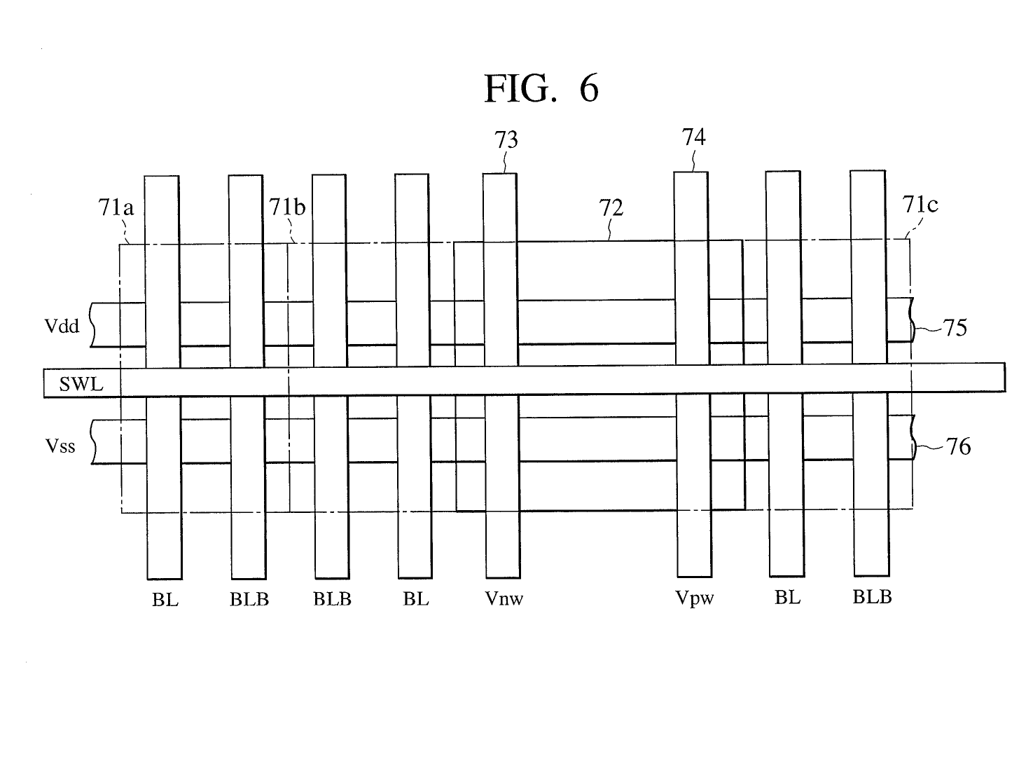

FIG. 6 is a layout model showing memory cell blocks and related elements of the SRAM of FIG. 1 according to the present invention. Generally, memory cells are formed in parallel with one another, and bit lines BL and /BL (BL bar, or BLB) are formed in the vicinities of the memory cells. Circuits for selecting lines such as word lines and circuits for driving such lines are usually arranged in a non-memory cell area. The example of FIG. 6 has a non-memory cell area 72 between memory cell blocks 71b and 71c. In the non-memory cell area 72, the present invention arranges a line 73 for supplying Vnw and a line 74 for supplying Vpw. The lines 73 and 74 may run in parallel with the bit lines and may be formed in the same layer as the bit lines. The non-memory cell area 72 usually contains no bit lines, and therefore, the lines 73 and 74 can be formed in the non-memory cell area 72. Through the lines 73 and 74, this embodiment according to the present invention supplies a plurality of voltages to wells. Arranging the lines 73 and 74 in parallel with the bit lines realizes iterated patterns to be optically formed. This improves dimensional controllability. Arranging the lines 73 and 74 in the non-memory cell area 72, which is an existing space, prevents increasing in area.

This embodiment according to the present invention may form the switches 41 and 42 in the non-memory cell area 72. More precisely, the switches may be formed at intersections of the lines 73 and 74, which are formed in the non-memory cell area 72, with lines 75 and 76 for supplying Vdd and Vss. The level shifters 31 and 34 may be arranged in an area where a driver for driving the section word line SWL is formed, to cause no increase in patterns.

The above embodiment applies substrate potentials (Vnw, Vpw) to the n-well 20 and p-well 30, respectively. This configuration may require a triple well structure. Since the pMOS transistors in the n-well 20 function only as load, it is possible to control only the substrate potential of the p-well 30. If an n-type substrate is employed, the effect of the present invention is achievable without the triple well structure. This is advantageous in saving costs. It is also possible to control only the substrate potential of the n-well 20. The switching of substrate potentials and the selection of substrate potential values may properly be determined in such a way as to secure the effect of the present invention.

In summary, this embodiment according to the present invention provides a semiconductor memory capable of switching substrate potentials depending on situations (an operation period or a standby period), to reduce power consumption during the standby period and secure high-speed operation even at a low voltage during the operation period. Consequently, the present invention is capable of providing large-capacity, high-speed, low-power-consumption SRAMs.

The present invention may be embodied in other specific forms without departing from the spirit or essential characteristics thereof. The embodiments are therefore to be considered in all respects as illustrative and not restrictive, the scope of the present invention being indicated by the appended claims rather than by the foregoing description, and all changes which come within the meaning and range of equivalency of the claims are therefore intended to be embraced therein.

What is claimed is:

1. A semiconductor memory with static memory cells, comprising:
a first-conductivity-type well contained in the memory cells, configured to include second-conductivity-type transistors;
a second-conductivity-type well contained in the memory cell, configured to include first-conductivity-type transistors;
a first power source line configured to supply a first voltage;
a second power source line configured to supply a second voltage;
a third power source line configured to supply a third voltage; and
first switch coupled to the first and second power source lines, configured to provide the first-conductivity-type well with one of the first and second voltages in response to a switching signal.

2. The semiconductor memory as claimed in claim 1, wherein the first switch provides the first-conductivity-type well with the second voltage if the memory cell is in a standby state, and the first switch provides the first-conductivity-type well with the first voltage if the memory cell is in a selected state.

3. The semiconductor memory as claimed in claim 2, wherein the first-conductivity-type well is a p-type well, and the second-conductivity-type transistors are n-type transistors.

4. The semiconductor memory as claimed in claim 3, wherein the first voltage is higher than the second voltage.

5. The semiconductor memory as claimed in claim 2, wherein the first-conductivity-type well is an n-type well, and the second-conductivity-type transistors are p-type transistors.

6. The semiconductor memory as claimed in claim 5, wherein the first voltage is lower than the second voltage.

7. The semiconductor memory as claimed in claim 1, wherein the first switch supplies one of the first and second voltage to each memory cell block.

8. The semiconductor memory as claimed in claim 1, wherein the second-conductivity-type transistors are MIS (metal insulator semiconductor) transistors.

9. The semiconductor memory as claimed in claim 1, further comprising:
a fourth power source line configured to supply a fourth voltage; and
second switch coupled to the third and fourth power source lines, configured to provide the second-conductivity-type well with one of the third and fourth voltages in response to the switching signal.

10. The semiconductor memory as claimed in claim 9, wherein:
the first switch provides the first-conductivity-type well with the second voltage if the memory cell is in a standby state, and the first switch provides the first-conductivity-type well with the first voltage if the memory cell is in a selecting state; and
the second switch provides the second-conductivity-type well with the fourth voltage if the memory cell is in the standby state, and the second switch provides the second-conductivity-type well with the third voltage if the memory cell is in the selected state.

11. The semiconductor memory as claimed in claim 10, wherein the first-conductivity-type well is a p-type well, the second-conductivity-type transistors are n-type transistors, the second-conductivity-type well is an n-type well, and the first-conductivity-type transistors are p-type transistors.

12. The semiconductor memory as claimed in claim 11, wherein the first voltage is higher than the second voltage, and the third voltage is lower than the fourth voltage.

13. The semiconductor memory as claimed in claim 9, wherein:
the first switching means supplies one of the first and second voltages memory cell by memory cell; and
the second switching means supplies one of the third and fourth voltages memory cell to each memory cell block.

14. The semiconductor memory as claimed in claim 9, wherein the first-conductivity-type and second-conductivity-type transistors are MIS (metal insulator semiconductor) transistors.

15. The semiconductor memory as claimed in claim 1, wherein the switching signal is an SWL (section word line) signal.

16. The semiconductor memory as claimed in claim 1, wherein the first switch is formed in a non-memory cell area where a driver for driving a section word line is formed.

17. The semiconductor memory as claimed in claim 16, wherein the second power source line is formed in the non-memory cell area.

18. The semiconductor memory as claimed in claim 17, wherein the second power source line is substantially in parallel with bit lines.

19. A semiconductor memory with static memory cells, comprising:
a first-conductivity-type well contained in each of the memory cells and including second-conductivity-type transistors;
a second-conductivity-type well contained in the memory cell and including first-conductivity-type transistors;
a first power source line coupled to the first-conductivity-type well, configured to supply one of first and second voltages;
a second power source line configured to supply a third voltage; and
switching means coupled to the first power source line, configured to provide the first power source line with one of the first and second voltages in response to a switching signal.

20. The semiconductor memory as claimed in claim 19, wherein the first switch provides the first-conductivity-type well with the second voltage if the memory cell is in a standby state, and the first switch provides the first-conductivity-type well with the first voltage if the memory cell is in a selected state.

21. The semiconductor memory as claimed in claim 20, wherein the first-conductivity-type well is a p-type well, and the second-conductivity-type transistors are n-type transistors.

22. The semiconductor memory as claimed in claim 21, wherein the first voltage is higher than the second voltage.

23. The semiconductor memory as claimed in claim 20, wherein the first-conductivity-type well is an n-type well, and the second-conductivity-type transistors are p-type transistors.

24. The semiconductor memory as claimed in claim 23, wherein the first voltage is lower than the second voltage.

25. The semiconductor memory as claimed in claim 19, wherein the first switch supplies one of the first and second voltages to each memory cell block.

26. The semiconductor memory as claimed in claim 19, wherein the second-conductivity-type transistors are MIS (metal insulator semiconductor) transistors.

27. The semiconductor memory as claimed in claim 19, further comprising:
a fourth power source line configured to supply a fourth voltage; and
second switch coupled to the third and fourth power source lines, configured to provide the second-conductivity-type well with one of the third and fourth voltages in response to the switching signal.

28. The semiconductor memory as claimed in claim 27, wherein:
the first switch provides the first-conductivity-type well with the second voltage if the memory cell is in a standby state, and the first switch provides the first-conductivity-type well with the first voltage if the memory cell is in a selecting state; and
the second switch provides the second-conductivity-type well with the fourth voltage if the memory cell is in the standby state, and the second switch provides the second-conductivity-type well with the third voltage if the memory cell is in the selected state.

29. The semiconductor memory as claimed in claim 28, wherein the first-conductivity-type well is a p-type well, the second-conductivity-type transistors are n-type transistors, the second-conductivity-type well is an n-type well, and the first-conductivity-type transistors are p-type transistors.

30. The semiconductor memory as claimed in claim 29, wherein the first voltage is higher than the second voltage, and the third voltage is lower than the fourth voltage.

31. The semiconductor memory as claimed in claim 27, wherein:
the first switching means supplies one of the first and second voltages memory cell by memory cell; and
the second switching means supplies one of the third and fourth voltages memory cell by memory cell.

32. The semiconductor memory as claimed in claim 27, wherein the first-conductivity-type and second-conductivity-type transistors are MIS (metal insulator semiconductor) transistors.

33. The semiconductor memory as claimed in claim 19, wherein the switching signal is an SWL (section word line) signal.

34. The semiconductor memory as claimed in claim 19, wherein the switching means includes:
a level shifter containing:
an input terminal configured to receive the switching signal;
a first output terminal; and
a second output terminal,
wherein the level shifter provides one of the first and second output parts with an ON signal in response to the switching signal;
a first transistor circuit coupled to the first output part, for providing the first power source line with the first voltage in response to the ON signal; and
a second transistor circuit coupled to the second output part, for providing the first power source line with the second voltage in response to the ON signal.

35. The semiconductor memory as claimed in claim 19, wherein the first switch is formed in a non-memory cell area where a driver for driving a section word line is formed.

36. The semiconductor memory as claimed in claim 35, wherein the second power source line is formed in the non-memory cell area.

37. The semiconductor memory as claimed in claim 36, wherein the second power source line is substantially in parallel with bit lines.
